(19) United States
(12) Patent Application Publication
(10) Pub. No.: US 2009/0087973 A1
(43) Pub. Date: Apr. 2, 2009

(54) RETENTION IMPROVEMENT IN DUAL-GATE MEMORY

(76) Inventor: Andrew J. Walker, Mountain View, CA (US)

Correspondence Address: MACPHERSON KWOK CHEN & HEID LLP, 2033 GATEWAY PLACE, SUITE 400, SAN JOSE, CA, 95110, US

(21) Appl. No.: 12/240,848

(22) Filed: Sep. 29, 2008

Related U.S. Application Data
(60) Provisional application No. 60/977,007, filed on Oct. 2, 2007.

(51) Int. Cl. H01L 21/3205

(52) U.S. Cl. 438/591; 257/E21.209

(57) ABSTRACT

A manufacturing process improves retention capabilties of dual-gate non-volatile memory cells by limiting the effects of lateral charge movement. The process limits lateral extents of the charge storage medium that is an integral part of the memory device within the dual-gate device.

### CROSS REFERENCE TO RELATED APPLICATIONS

The present application relates to and claims priority of U.S. provisional patent application (“Provisional Application”), entitled “Retention Improvement in Dual-Gate Memory,” Ser. No. 60/977,007, filed on Oct. 2, 2007. The disclosure of the Provisional Application is hereby incorporated by reference in its entirety.

### BACKGROUND OF THE INVENTION

1. Field of the Invention

The present invention relates to methods for optimizing charge retention in nonvolatile memories consisting of strings of serially connected dual-gate memory cells.

2. Discussion of the Related Art

Thin-film transistors having silicon nitride as the charge storage medium may be used as building blocks for three-dimensionally integrated non-volatile memories. In that regard, the article “3D-TFT SONOS Memory Cell for Ultra-High Density File Storage Applications” (“Walker”), by Walker et al., published in the Symposium on VLSI Technology, Kyoto 2003, reported the results of making a nonvolatile memory cell using a single-gated thin-film transistor. Similarly, the article “Three Dimensionally Stacked NAND Flash Memory Technology Using Stacking Single Crystal Si Layers on ILD and TANOS Structure for Beyond 30 nm Node” (“Jung”), by Jung et al., published in the Procedings of the International Electronic Device Meeting (IEDM), 2006, introduced a NAND string that consists of a first layer of memory cells formed in the bulk of a silicon wafer with a second layer of memory cells built on top of and isolated from the first layer of memory cells. The second layer of memory cells consists of single-gated thin-film transistors formed in a thin layer of crystalline silicon. The storage medium in both layers of memory cells is a stack structure known as TANOS, which consists of a layer tantalum nitride gate electrode material in contact with a layer of aluminum oxide dielectric material. The aluminum oxide dielectric material is deposited on top of a layer of silicon nitride which, in turn, is deposited on top of a silicon dioxide layer.

In series-connected transistors that act as nonvolatile memory cells with nitride charge storage (e.g., in Jung's NAND configuration), lateral charge motion within the nitride-containing charge-trapping medium is a problem. Lateral charge motion within the charge-trapping medium results in both a charge retention problem and a difficulty in maintaining clear distinction between the erased and programmed threshold voltages. Lateral charge motion is discussed in the article “Self Aligned Trap-Shallow Trench Isolation Scheme for the Reliability of TANOS (TaN/AlO/SiN/Oxide/Si) NAND Flash Memory,” by Sim et al., published in the 22^{nd} IEEE Non-Volatile Semiconductor Memory Workshop, August 2007.

Dual-gate devices achieve high density integrated circuits (e.g., non-volatile memories). Examples of dual-gate devices and their use may be found in (a) copending U.S. patent application (the “'462 Application”), entitled “Dual-Gate Device and Method,” by Walker, Ser. No. 11/197,462, filed on Aug. 3, 2005; and (b) copending U.S. patent application (the “'231 Application”), entitled “Dual Gate Device and Method,” by Walker, Ser. No. 11/548,231, filed on Oct. 10, 2006. The '462 Application and the '231 Application are hereby incorporation by reference in their entireties.

### SUMMARY OF THE INVENTION

The present patent application describes a method for preventing lateral charge motion and addresses data retention issues in dual-gate non-volatile memory cells. According to the present invention, a method limits the lateral extent of the charge-trapping medium (e.g., silicon nitride) in a dual-gate non-volatile memory cell. In this way, retention problems associated with lateral motion of charge can be minimized.

The present invention is better understood upon consideration of the detailed discussion below, in conjunction with the drawings.

### DESCRIPTION OF THE DRAWINGS

FIG. 1 is a schematic cross-section of dual-gate memory cell 100 formed by a memory device and a non-memory or access device.

FIG. 2 is a graphical representation 200 of a dual-gate device, indicating gate electrode 201 of the memory device, and gate electrode 202 of the access device, with source and drain connections 203 and 204.

FIGS. 3A-3N illustrate a process flow that results in formation of dual-gate memory cells each having a limited lateral extent in the charge storage medium; the extent of each memory cell's charge storage medium is limited in both the word line and channel directions.

### DETAILED DESCRIPTION OF THE PREFERRED EMBODIMENT

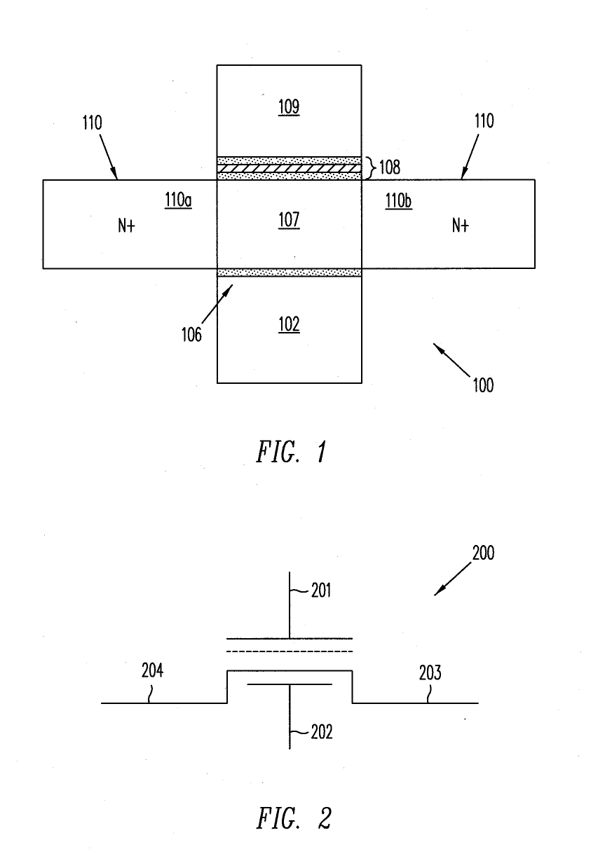

FIG. 1 is a schematic cross-section of dual-gate memory cell 100 formed by a memory device and a non-memory device (also, referred to as an “access device”). As shown in FIG. 1, the access device includes gate dielectric 106 and gate electrode 102 and the memory device includes gate dielectric stack 108 and gate electrode 109. Gate dielectric stack 108 includes a charge-trapping layer that stores charge in a non-volatile fashion. The memory and access devices share source and drain regions 110 and active region 107., Although shown having the memory device formed above the access device, these device may be formed in the reverse order—i.e., with the memory device formed underneath the access device. FIG. 2 is a graphical representation 200 of a dual-gate device, indicating gate electrode 201 of the memory device, and gate electrode 202 of the access device, with source and drain connections 203 and 204.

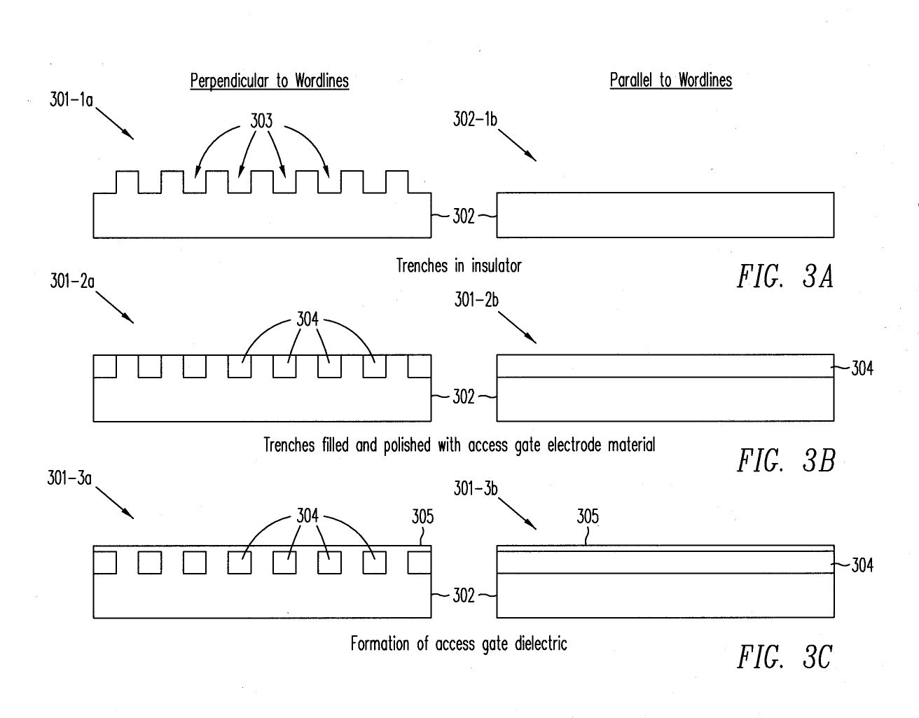

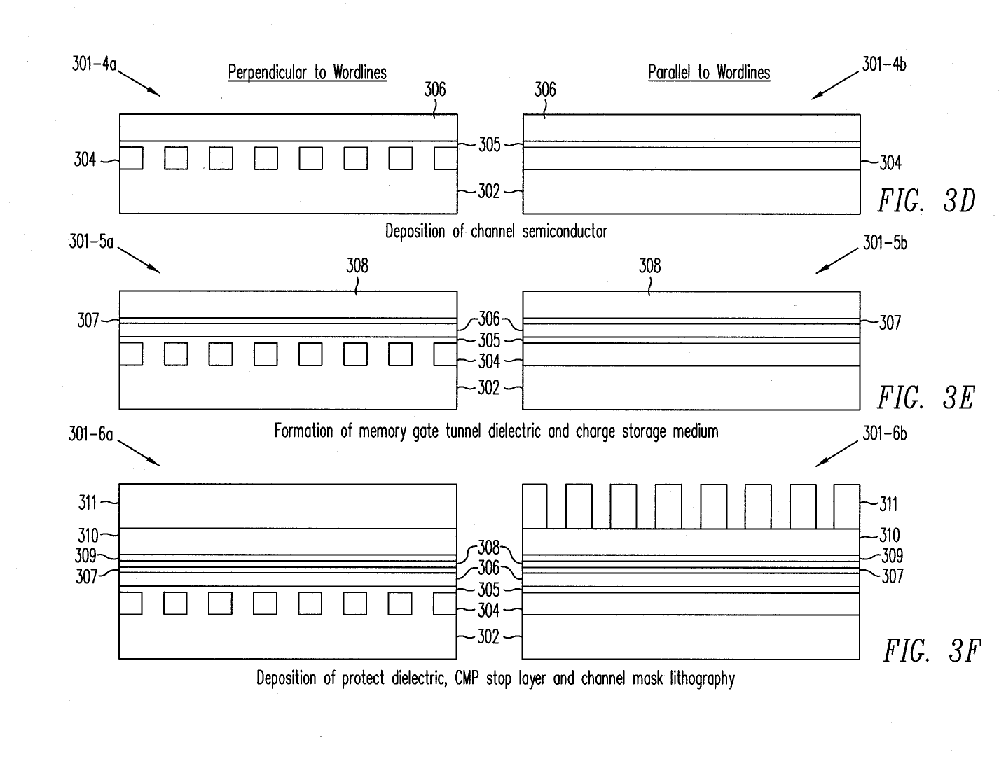

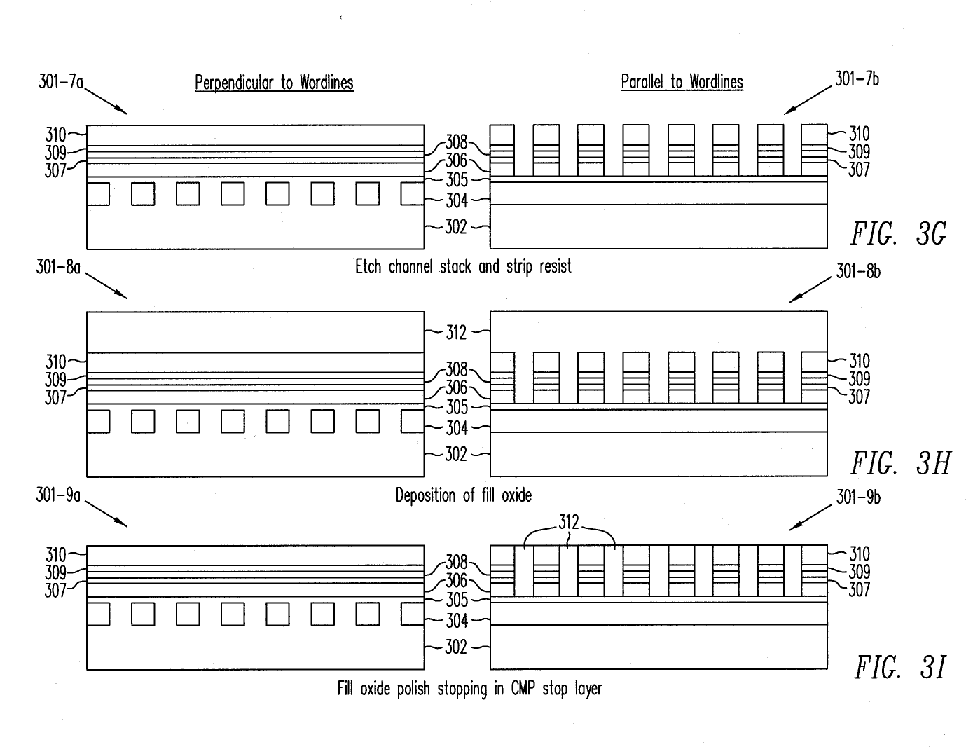

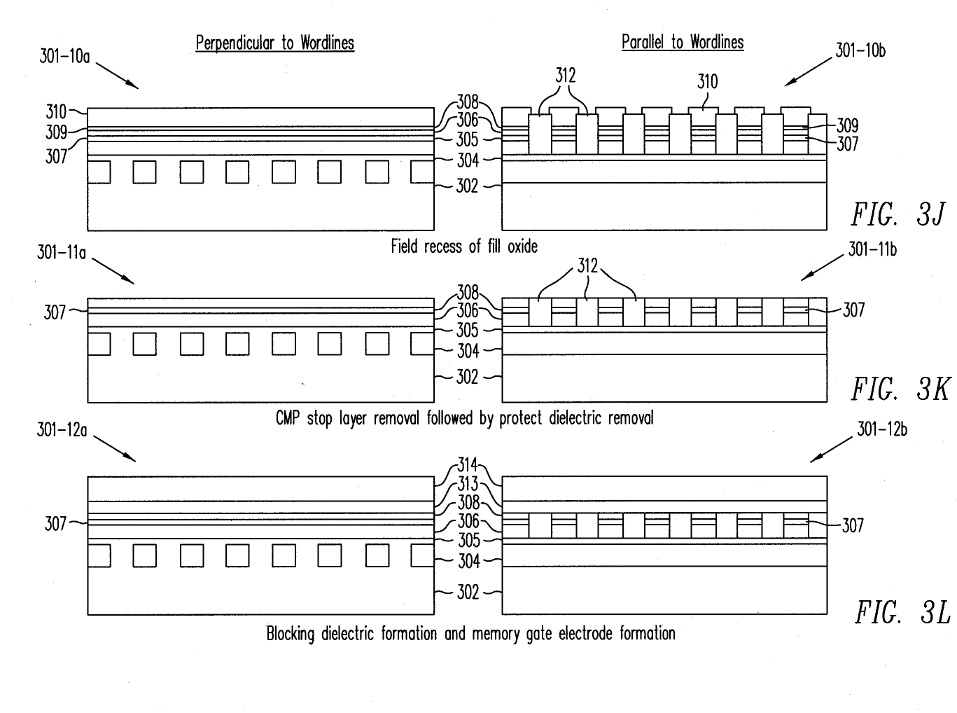

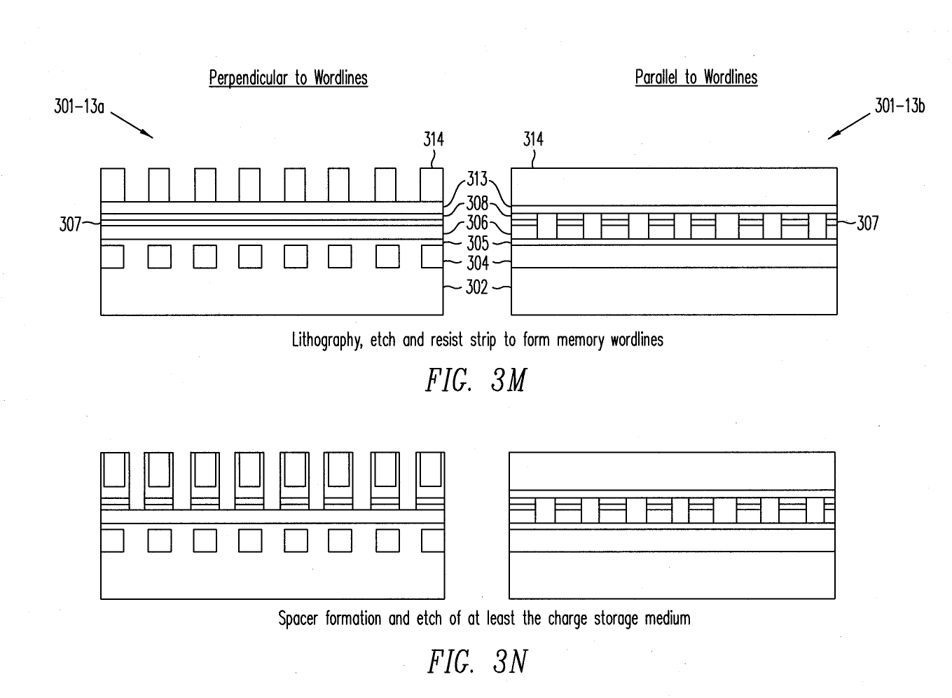

The advantages of dual-gate non-volatile memory cells are discussed, for example, in the '462 Application and the '231 Application, which are incorporated by reference above. One way to improve charge retention in the charge storage medium of a dual-gate non-volatile memory cell is to limit the lateral extent of this charge storage medium. FIGS. 3A-3N illustrate a process flow that results in formation of dual-gate memory cells each having a limited lateral extent in the charge storage medium. The extent of each memory cell's charge storage medium is limited in both the word line and channel directions.

FIG. 3A shows cross sections 301a and 301b through a silicon wafer in a manufacturing process for forming dual-gate memory cells on semiconductor substrate 302. Cross sections 301-1a and 301-1b show the silicon wafer in a direction perpendicular to the direction of word lines (i.e., gate electrodes) and parallel to the word lines, respectively. As shown in FIG. 3A, trenches 303 are formed within thick dielectric layer 302, which may be provided by a deposited silicon dioxide over active bulk circuitry (not shown). Then, as shown in cross sections 301-2a and 301-2b of FIG. 3B, gate electrodes 304 of the access devices of the dual-gate memory cells are formed within trenches 303 by, for example, depositing a conducting material (e.g., doped polysilicon or a metal, such as tungsten). The surface of gate electrodes 303 are then planarized using a chemical mechanical polishing (CMP) technique. Alternatively, gate electrodes of the access devices may also be formed by etching a deposited conductor layer after pattern development using a photolithographical technique. A gap-filling oxide layer is then deposited between and on top of gate electrodes 304. A CMP technique can be applied to planarize the deposited gap-filling oxide layer. In one embodiment, a CMP stop layer may be provided on gate electrodes 304 that may be subsequently removed after CMP planarization.

After planarization, as shown in cross sections 301-3a and 301-3b of FIG. 3C, gate dielectric layer 305 for the access device is then formed, using a known step such as thermal oxidation, low-pressure chemical vapor deposition (LPCVD), atomic layer deposition (ALD), or a combination of these approaches. One embodiment provides a silicon dioxide layer as access gate dielectric layer 305 that is between 5 nm and 40 nm thick.

FIG. 3D shows channel semiconductor layer 306 being provided as a deposited layer of amorphous silicon, amorphous germanium, polycrystalline silicon or germanium or a combination of silicon and germanium. Channel semiconductor layer 306 may be crystallized to enhance the mobility of the mobile charge carriers when an inversion layer is created electrically in channel semiconductor layer 306. The enhanced mobility advantageously increases read currents. Then, tunnel dielectric layer 307 is formed, as shown in cross sections 301-5a and 301-5b of FIG. 3E, using oxidation, LPCVD, or ALD or some combination of these techniques. Tunnel dielectric layer 307 may be between 1.5 nm and 8 nm thick.

Charge storage medium 308 is then deposited, typically by depositing silicon nitride using an LPCVD technique (FIG. 3E). Charge storage medium 308 may be provided by a silicon-rich silicon nitride, oxygen-rich silicon nitride or any silicon nitride material having a range of spatial variations of silicon and oxygen. Alternatively, charge storage medium 308 may consist of a nitride-oxide-nitride (N—O—N) stack instead of simply silicon nitride. Charge storage medium 308 may be between 5 nm and 20 nm thick.

Thereafter, silicon oxide protective layer 309 and CMP stop layer 310 (e.g., a silicon nitride layer) are deposited in order. Using a photolithographical technique, photosensitive resist layer 311 is provided, exposed, and developed to provide a channel mask structure. The resulting cross sections 301-6a and 301-6b are shown in FIG. 3F.

FIG. 3G illustrates the channel stack etch, followed by stripping of photoresist layer 311. The channel stack etch stops at dielectric layer 305 of the access device or at gate electrodes 304 of the access devices. Then, as shown in FIG. 3H, a gap fill procedure is carried out, which consists of the depositing silicon oxide layer 312 using, for example, high density plasma (HDP), or any form of undoped silicate glass (USG). The gap fill procedure fills the gaps between etched features and deposits additional silicon oxide on top of CMP stop layer 310. A CMP step may be carried out, stopping in CMP stop layer 310, as shown in FIG. 31. The extent of charge storage medium 308 is therefore limited in the direction parallel to the word lines, as illustrated in cross section 301-8b of FIG. 3H.

An oxide etch, illustrated in cross section 301-10b of FIG. 3J, removes a portion of gap fill oxide layer 312 from the gaps to result in a field recess. This oxide etch step allows the eventual structure to be more planar, to accommodate the steps to be described below. CMP stop layer 310 and protective dielectric layer 309 are then removed using, for example, a chemical wet etch (e.g., phosphoric acid and hydrofluoric acid). The resulting structure is shown in FIG. 3K.

Blocking dielectric layer 313 for the memory devices is then deposited to a thickness of 4 nm to 15 nm and may consist of high temperature oxide (HTO) deposited using, for example, an LPCVD technique. Alternatively, blocking dielectric layer 313 may be provided by a high-k dielectric material (e.g., an aluminum oxide layer with a thickness between 8 nm and 20 nm) deposited using an ALD technique. Next, gate electrode layer 314 (i.e., word line) for the memory devices is formed out of a conducting material such as highly doped polysilicon (n-doped or p-doped), tantalum nitride (TaN), titanium nitride (TiN), tungsten nitride (WN), titanium disilicide, nickel silicide, cobalt silicide, tungsten, or a combination of two or more of these conducting materials. The resulting structure is shown in FIG. 3L.

FIG. 3M shows gate electrode layer 314 being patterned to form the word lines using a photolithographical technique, etching and resist stripping. An oxidation step or oxide deposition step followed by etching forms spacers on the exposed sides of gate electrode layer 314 of the memory devices. Either during etching of gate electrode layer 314 or during the subsequent spacer formation step, the underlying charge storage medium 308 exposed to the respective etchant may be removed, resulting in a further limiting the lateral extent of charge storage medium 308, thus enhancing charge retention.

A method has been shown to limit the lateral extent of the charge storage medium in a dual-gate memory device thus allowing for an improvement in the retention capability of this non-volatile memory.

The above detailed description is provided to illustrate specific embodiments of the present invention and is not intended to be limiting. Numerous variations and modifications within the scope of the present invention are possible. The present invention is set forth in the following claims.

I claim:

1. A method for forming non-volatile memory cells, comprising:
providing a semiconductor layer;
providing a first dielectric layer on the semiconductor layer,
providing a charge storage layer over the first dielectric layer;
etching the first dielectric layer and the charge storage layer according to a first etch pattern, the etch pattern substantially limiting lateral extents of the charge storage layer and the semiconductor layer in each of the memory cells along a first direction;
providing a second dielectric layer over the charge storage layer;
providing a conductive layer over the second dielectric layer; and
etching the charge storage layer a second time to substantially limit lateral extents of the charge storage layer in each of the memory cells along a second direction orthogonal to the first direction.

2. A method as in claim 1, wherein etching the charge storage layer a second time is carried out together with etching the conductive layer according to a second etch pattern.

3. A method as in claim 1, wherein etching the charge storage layer a second time is carried out together with forming spacers on sidewalls of the conductively layer.

4. A method as in claim 1, further comprising providing a gap-filling dielectric material to fill gaps created by the first etch pattern.

5. A method as in claim 4, further comprising:
prior to etching the first dielectric layer, providing a chemical mechanical polishing stop layer over the charge storing layer; and
after providing the gap-filling dielectric material, applying chemical mechanical polishing until the chemical mechanical polishing stop layer is reached; and
removing the chemical mechanical polishing stop layer.

6. A method as in claim 5, wherein a protective dielectric layer is provided on the charge storage layer prior to providing the chemical mechanical polishing stop layer.

7. A method as in claim 4, further comprising a field recess removal of the gap-filling dielectric material.

8. A method as in claim 1, wherein the non-volatile memory cells are dual-gate memory cells and wherein, in each dual-gate memory cell, the semiconductor layer is shared between the access device and the memory device of the dual-gate memory cell.

9. A method as in claim 1, wherein the semiconductor layer comprises a material selected from the group consisting of amorphous silicon, amorphous germanium, polycrystalline silicon, polycrystalline germanium, and a combination of silicon and germanium in any form.

10. A method as in claim 1, wherein the first dielectric layer is provided a thickness that allows tunneling of charge carriers between the semiconductor layer and the charge storing layer.

11. A method as in claim 1, wherein the charge storage layer comprises a material selected from the group consisting of silicon nitride, silicon-rich silicon nitride, oxygen-rich silicon nitride and a spatially varied combination of silicon oxide and silicon nitride.

12. A method as in claim 11, wherein the charge storage layer is deposited using a low pressure chemical vapor deposition technique.

13. A method as in claim 1, wherein the second dielectric layer comprises a material selected from the group consisting of silicon oxide and a high dielectric constant material.

14. A method as in claim 13, wherein the silicon oxide is a deposited high temperature oxide.

15. A method as in claim 13, wherein the high dielectric constant material comprises aluminum oxide deposited using atomic layer deposition.

16. A method as in claim 1, wherein the conducting material is selected from the group consisting of polysilicon, tantalum nitride, titanium nitride, tungsten nitride, titanium disilicide, nickel silicide, cobalt silicide, tungsten or a combination of two or more materials from the group.
